(19) United States
(12) Patent Application Publication
(10) Pub. No.: US 2015/0359098 A1
(43) Pub. Date: Dec. 10, 2015

(54) Circuit Board Having Interposer Embedded Therein, Electronic Module Using Same, and Method for Manufacturing Same

(71) Applicant: HANA MICRON INC., Asan-si, Chungcheongnam-do (KR)

(72) Inventor: Jin Young Ock, Gyeonggi-do (KR)

(21) Appl. No.: 14/758,195

(22) PCT Filed: Jul. 24, 2013
(86) PCT No.: PCT/KR2013/006651

§ 371 Date: Jun. 26, 2015

(30) Foreign Application Priority Data
Dec. 26, 2012 (KR) 10-2012-0153677

(51) Int. Cl. H05K 1/14; H05K 1/18; H05K 3/40; H05K 3/18; H05K 3/30; H05K 3/32; H05K 1/11; H05K 3/26

(52) U.S. Cl. CPC H05K 1/14; H05K 1/115; H05K 1/181; H05K 3/26; H05K 3/181; H05K 3/303; H05K 3/32; H05K 3/4038; H05K 2201/10159

(57) ABSTRACT

The present invention relates to a circuit board having an interposer embedded therein, including: an interposer, the top side and back side of which are electrically connected by a first through-electrode; and a molding member having the interposer embedded therein and the top side and back side of the interposer exposed. According to the present invention, the molding member of an insulator and the interposer of a semiconductor can be appropriately selected and coupled according to the required fine pitch of a through-hole, and the interposer is molded on substantially the same level as a semiconductor chip, and thus no additional process for embedding the interposer needs to be added.

### TECHNICAL FIELD

The present invention relates to a circuit board having an interposer embedded therein relevant to a fan-out wafer level package (WLP), and a manufacturing method thereof, and more particularly, to a circuit board having an interposer embedded therein that maintains the advantage of a fan-out insulating substrate and improves degree of integration of a circuit board, by applying a silicon interposer to only some sections requiring a fine-pitch through hole of a circuit board formed of an insulating material because a molding member being an insulator and an interposer being a semiconductor are coupled, and a manufacturing method thereof.

Also, the present invention relates to an electronic module using the circuit board having the interposer embedded therein and a manufacturing method thereof and more particularly to, an electronic module that has a semiconductor chip having a logic function embedded in the circuit board and has a semiconductor chip having a memory function and various passive elements stacked on the circuit board because various elements are packaged as the electronic module by using the circuit board having the interposer, and a manufacturing method thereof.

### BACKGROUND ART

In order to supplement the disadvantage of a wafer level package (WLP) limited generally to a semiconductor chip size, a fan-out WLP technology is being introduced which expands a package area by the fan-out, holds a plurality of input/output (I/O) terminals in the expanded area and protects a semiconductor chip from an external shock.

In such a fan-out structure, a polymer is mostly used as an expansion material in order to ensure an insulating characteristic and mechanical strength. A laser drill process is mostly used for forming a through hole in the insulating material such as a polymer. The laser drill process is useful for forming a through hole having a certain pitch or more but it is not longer possible to realize the fine pitch of the through hole with the laser drill process because the circuit board formed of the insulating material also needs degree of integration in light of the reduction of a design rule and the general miniaturization trend of a product.

### DISCLOSURE OF THE INVENTION

### Technical Problem

The present invention is devised to solve the limitation of the related art as described above and provides a circuit board having an interposer embedded therein that may realize the fine pitch of a through hole in a circuit board being an insulator in a fan-out WLP structure, an electronic module using same and a manufacturing method thereof.

### Technical Solution

In one embodiment, a circuit board having an interposer embedded therein includes an interposer having a top side and a back side that are electrically connected by a first through-electrode; and a molding member in which the interposer is embedded, wherein the molding member exposes the top side and back side of the interposer.

In another embodiment, an electronic module using a circuit board having an interposer embedded therein includes an interposer having a top side and a back side that are electrically connected by a first through-electrode; and a first element disposed on substantially a same plane as the interposer; and a molding member in which the interposer and the first element are embedded, wherein a second through-electrode electrically connects top and back sides of the molding member.

### Advantageous Effects

As described above, the following effects may be expected according to a configuration of the present invention.

Firstly, since an interposer being a semiconductor is partly coupled to a circuit board being an insulator, there are effects that the mechanical strength of the entire circuit board is maintained as it is and degree of integration is enhanced through the fine-pitch function of the interposer.

Secondly, since the interposer is disposed on a carrier, an insulating material is molded and the interposer is exposed through a polishing process, there is an effect that it is possible to easily dispose the interposer in a required section.

Thirdly, since a semiconductor chip having a logic function is embedded along with the interposer, it is possible to realize a wafer level package.

Fourthly, since semiconductor chips having a memory function are disposed on the circuit board in a vertically stacked manner and these are electrically connected through the through-electrode of the interposer, it is possible to realize an optimal 3D package structure.

### BRIEF DESCRIPTION OF THE DRAWINGS

FIG. 1 is a cross-sectional view of a circuit board having an interposer embedded therein according to the present invention.

FIGS. 2 to 5 are cross-sectional views of various embodiments of an electronic module using a circuit board having an interposer embedded therein according to the present invention.

FIGS. 6A to 6D are cross-sectional views of a manufacturing method of an interposer according to the present invention.

FIGS. 7A to 7G are cross-sectional views of a manufacturing method of FIG. 1.

FIGS. 8A to 8G are cross-sectional views of a manufacturing method of FIG. 4.

### MODE FOR CARRYING OUT THE INVENTION

The advantages and features of the present invention, and implementation methods thereof will be clarified through the following embodiments described with reference to the accompanying drawings. The present invention may, however, be embodied in different forms and should not be construed as limited to the embodiments set forth herein. Rather, these embodiments are provided to make this disclosure complete and fully convey the scope of the present invention to a skilled in the art. Further, the present invention is only defined by the scopes of claims. In the drawings, the size and relative size of layers and regions may be exaggerated for the clarification of description. Like reference numerals throughout the disclosure refer to like components.

Embodiments described in the disclosure are described with reference to plane views and cross-sectional views that are ideal, schematic diagrams of the present invention. Thus, the forms of exemplary views may vary depending on manufacturing technologies and/or tolerances. Thus, embodiments of the present invention are not limited to shown specific forms and also include variations in form produced according to manufacturing processes. Thus, regions illustrated in the drawings are exemplary, and the shapes of the regions illustrated in the drawings are intended to illustrate the specific shapes of the regions of elements and not to limit the scope of the present invention.

In the following, exemplary embodiments of a circuit board having an interposer embedded therein and an electronic module according to the present invention having a configuration as described above are described in detail with reference to the accompanying drawings.

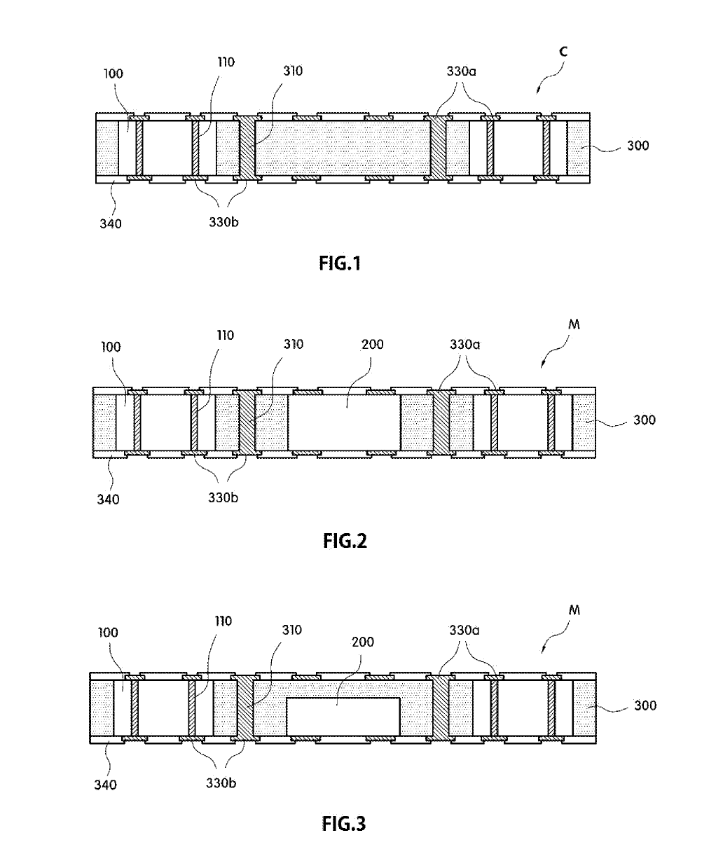

FIG. 1 is a cross-sectional view of a circuit board having an interposer embedded therein according to the present invention and FIGS. 2 to 5 are cross-sectional views of an electronic module using a circuit board having an interposer embedded therein according to the present invention.

Referring to FIG. 1, the circuit board C of the present invention relates to a base formed by coupling an interposer 100 being a semiconductor to a molding member 300 being an insulator. Referring to FIG. 2, the electronic module M of the present invention relates to a semiconductor package in which a first element 200 is embedded in the circuit board C along with the interposer 100. In the following, since the electronic module M of FIG. 2 includes the circuit board C of FIG. 1, FIG. 2 is mostly described.

Referring to FIG. 2, the interposer 100 and the first element 200 are embedded by the molding member 300 at substantially the same level, according to the electronic module M of the present invention.

The interposer 100 includes a first through-electrode 110 that electrically connects a top side T and a back side B. The first element 200 is disposed on substantially the same plane as the interposer 100. The interposer 100 is disposed in the molding member 300 along with the first element 200 and the top side T and the back side B of the interposer 100 are all exposed.

A top side T of the first element 200 and a back side B thereof may also be exposed. In another embodiment, referring to FIG. 3, the back side B of the first element 200 is exposed but the top side thereof may not be exposed. In another embodiment, though not shown, the backside B may not be exposed when the back side of the first element 200 includes an additional terminal. The first element 200 may be a logic semiconductor chip. Alternatively, it may be a memory semiconductor chip. When it is a semiconductor chip capable of implementing a wafer level package (WLP), there is no limitation.

The molding member 300 includes a second through-electrode 310 that electrically connects a top side T and a back side B. The diameter of the second through-electrode 310 is not smaller than that of that of the first through-electrode 110. The fine pitch of the first through-electrode 110 is not smaller than that of the second through-electrode 310.

As such, the circuit board C of the present invention includes the first element 200 therein and makes an electrical connection to function as the electronic module M. Also, the circuit board C of the present invention may be used for a semiconductor package having various elements installed outside. That is, a 3D-structure semiconductor package may be formed by using the circuit board C, according to the present invention. Thus, the first element 200 embedded in the circuit board C may make up the electronic module M along with a second element 400 and a third element 500 that are stacked on the circuit board C.

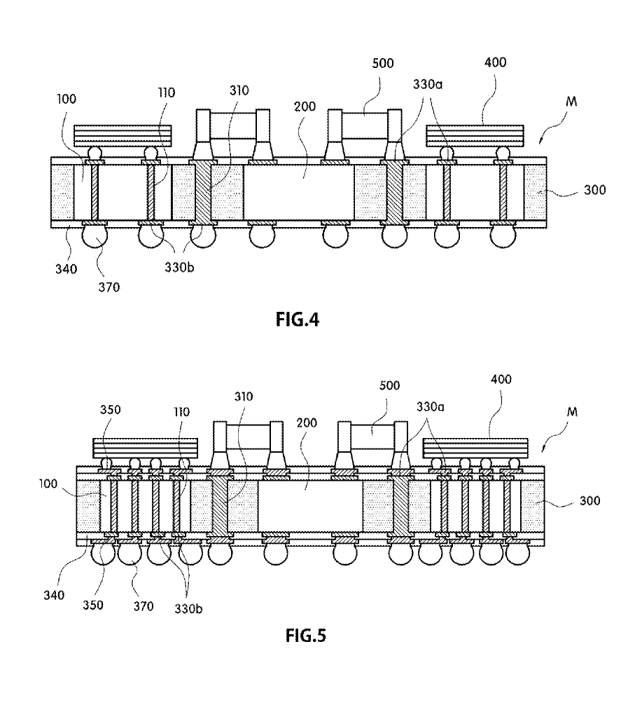

Referring to FIG. 4, the electronic module M may further include the first element 200 disposed in the circuit board C, and the second element 400 and the third element 500 that are mounted on the circuit board C. When the first element 200 is a logic semiconductor chip, the second element 400 may be a memory semiconductor chip. On the contrary, when the first element 200 is the memory semiconductor chip, the second element 400 may be the logic semiconductor chip. Various passive elements may be disposed on the circuit board C. Thus, the third element 500 may be a passive element that includes a resistor or a condenser. The first element 200 having a logic function, the second element 400 having a memory function, and the third element 500 being various passive elements make various combinations to be capable of making up electronic modules M having many functions.

The circuit board C may include an internal terminal 330a and an external terminal 330b in order to connect various elements to an external circuit (not shown). For example, an external terminal 330b may be further included so that the first element 200 is connected to the external circuit. Also, an internal terminal 330a and an external terminal 330b may be included so that the second element 400 is connected to the external circuit through the first through-electrode 110. The internal terminal 330a and the external terminal 330b may be included so that the third element 500 is connected to the external circuit through the second through-electrode 310. A passivation layer 340 that protects the circuit board C but exposes the internal/external terminals 330a and 330b may be formed with a certain thickness.

Referring to FIG. 5, the internal/external terminals 330a and 330b may be expanded onto the circuit board C through a redistribution pattern 350. According to the present invention, since the interposer 100 is used, the fine pitch of the first through-electrode 110 decreases and degree of integration increases, in which case the gap between the external terminals 300b should also be expanded when a plurality of solder bumps 370 needs to be formed in a fanned-out, expanded area. Thus, the redistribution pattern 350 may increase according to the degree of integration of the second element 400 or the third element 500 and the fine pitch of the first through-electrode 110.

In the following, a process of manufacturing the interposer is described in detail with reference to the drawings.

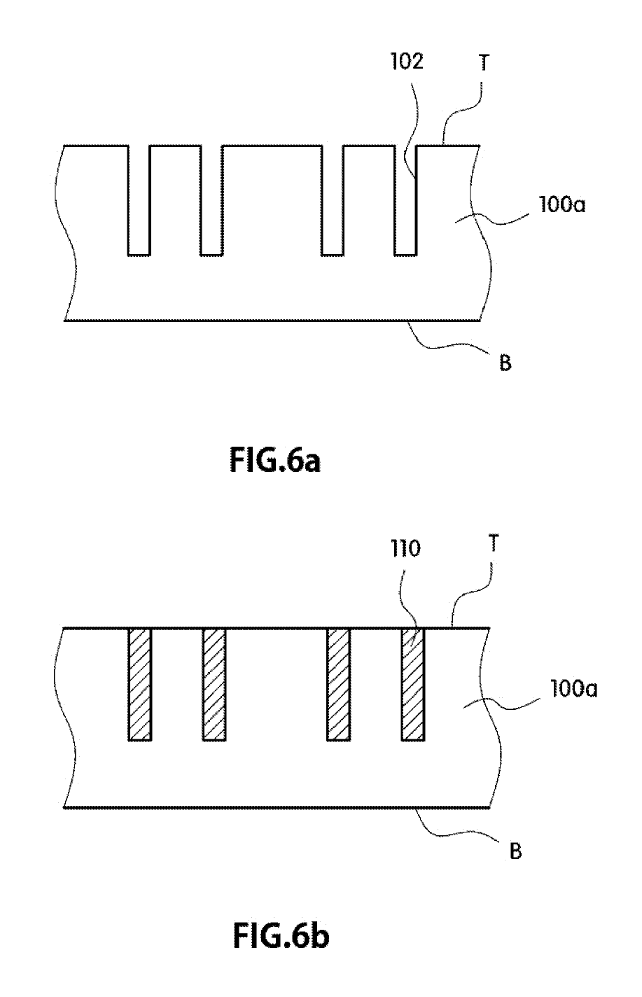

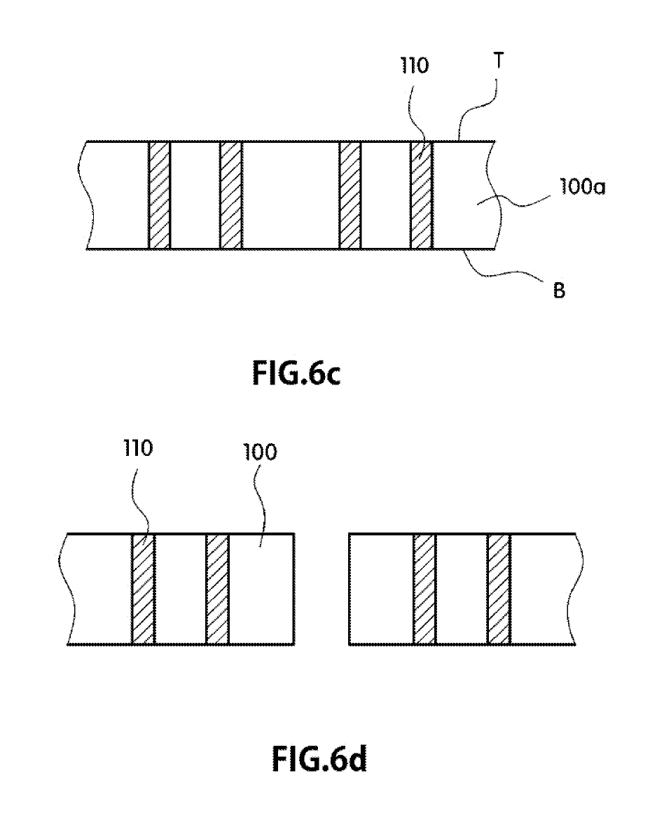

FIGS. 6A to 6D are cross-sectional views of a manufacturing method of an interposer according to the present invention.

Referring to FIG. 6A, an interposer substrate 100a is provided. By patterning the top side T of the interposer substrate 100a, a first via hole 102 is formed with a certain depth in the certain region of the interposer substrate 100a. The first via hole 102 may be formed through a photolithographic process. Alternatively, it may be formed through a laser process. In order to realize the fine pitch of the first via hole 102, it is assumed that the photolithographic process enabling easy precision processing is performed. When the photolithographic process is used, the first via hole 102 may be formed by a single process according to the aspect ratio of the first via hole 102 or through many processes.

Referring to FIG. 6B, the first through-electrode may be formed in the first via hole 102. Although not shown, an insulating layer may be formed on the top side T of the interposer substrate 100a including the first via hole 102. The insulating layer may be deposited with a certain thickness on the first via hole 102 including the top side T. The insulating layer may be formed of a silicon oxide layer through a PVD or CVD process. Although not shown, a barrier layer which prevents the diffusion of the first through-electrode 110 may be further formed on the insulating layer. The conductive material of the first through-electrode 110 may be formed by a plating process by using copper (Cu), in which case a seed layer may be first formed on the insulating layer. Alternatively, the conductive material of the first through-electrode 110 may be formed by a deposition process by using aluminum (Al). The conductive material filling the first via hole 102 is formed of the first through-electrode 110 through a chemical mechanical polishing (CMP) process. In this case, the barrier layer and seed layer on the top side T may be removed by the CMP process. As a result, the insulating layer and the barrier layer remain on only the first via hole 102.

Referring to FIG. 6C, the first through-electrode 110 may be exposed through a thin film process that removes the back side B of the interposer substrate 100a. Although not shown, the top side T of the interposer substrate 100a may be attached to a thinning carrier by using adhesive for a thinning process. That is, while the top side T of the interposer substrate 100a is fixed to the thinning carrier, the back side B may be processed. For example, the thin film process that exposes the first through-electrode 110 buried by using the chemical mechanical polishing (CMP) process or an etch back process.

Referring to FIG. 6D, the interposer substrate 100a may be divided into a plurality of interposers 100 through a dicing process. According to a typical interposer process, the redistribution layer (RDL) process and the passivation process may be included in the interposer substrate 100a in which the first through-electrode 110 is formed, but according to the present invention, the re-wiring process or the passivation process is omitted because the interposer 100 is embedded into the circuit board C and is electrically connected to other elements in the subsequent processes.

In the following, a method of manufacturing the circuit board C by using the interposer is described in detail with reference to the drawings.

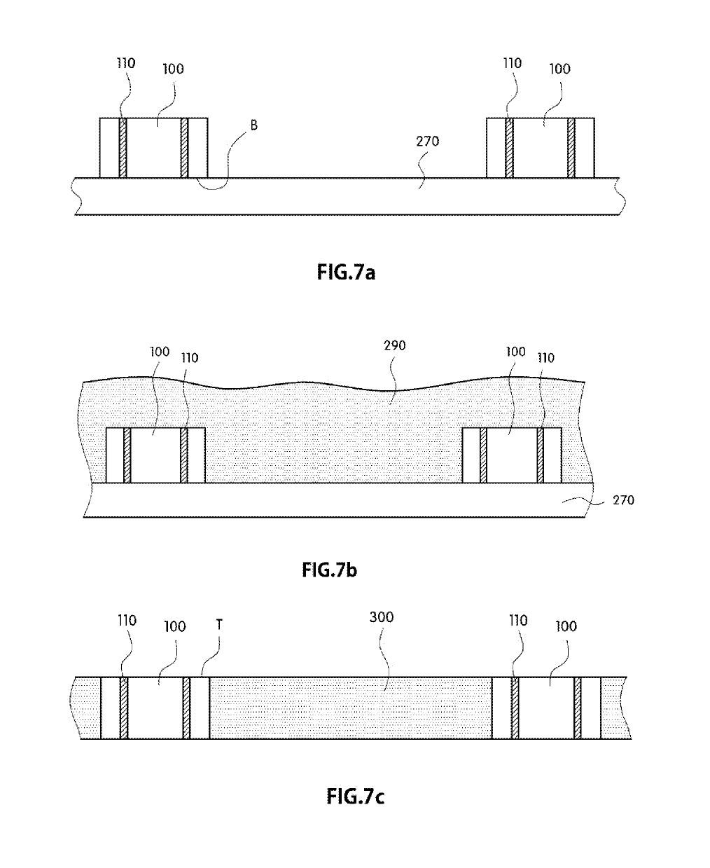

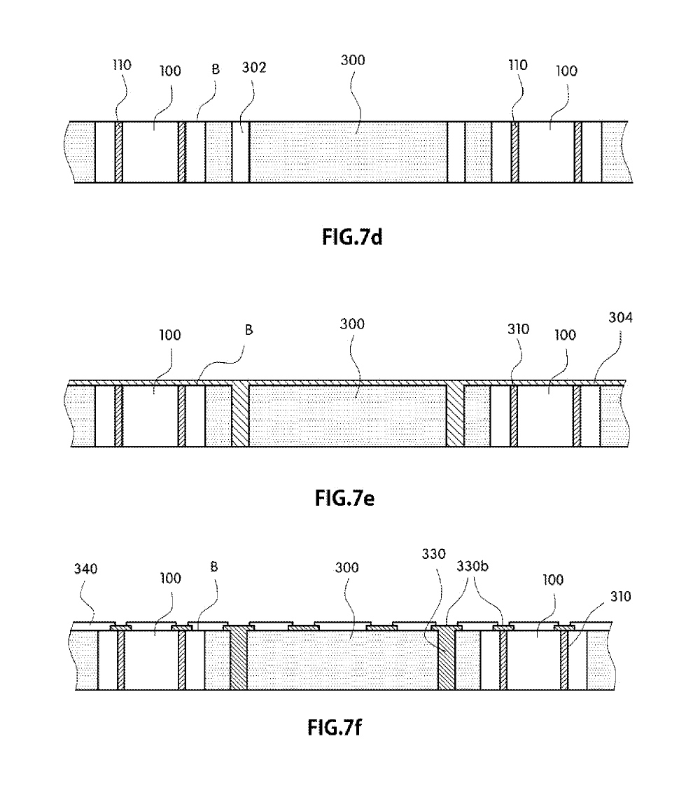

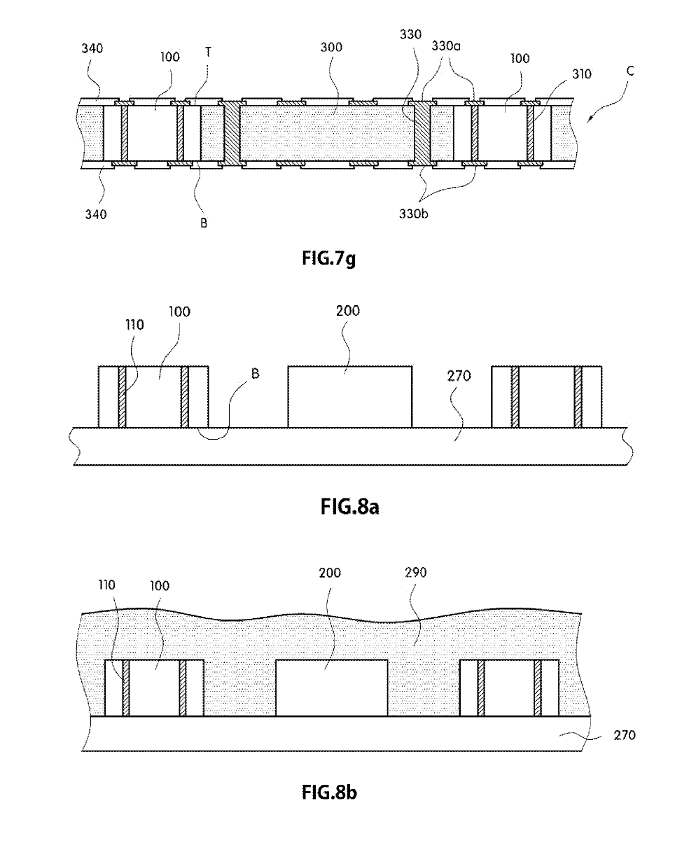

FIGS. 7A to 7G are cross-sectional views of a manufacturing method of the circuit board of FIG. 1, i.e., a method of manufacturing the circuit board C by using the interposer.

Referring to FIG. 7A, the interposers 100 manufactured by FIGS. 6A to 6D are arranged on a molding carrier 270. The back side B of the interposer 100 may be fixed to the molding carrier 270 by using adhesive. The adhesive may be epoxy or the like.

Referring to FIG. 7B, the molding carrier 270 is coated with an insulating material 290 so that the interposer 100 may be sufficiently covered. The insulating material 290 may be epoxy molding compound (EMC) or the like. The molding carrier is removed with the adhesive.

Referring to FIG. 7C, the CMP process is performed until the interposer 100 is exposed. A portion of the insulating material 290 is removed so that the top side T of the interposer 100 is exposed. Also, the first through-electrode 110 is also exposed. At the same time, the molding member 300 having substantially the same level as the top side T of the interposer 100 is formed.

Referring to FIG. 7D, by patterning the back side B of the molding member 300, a second via hole 302 passing through the molding member 300 is formed. The second via hole 302 may be formed through a photolithographic process or laser process. Since the second via hole 302 does not strictly require a fine pith in comparison to the first via hole 102, it does not necessarily need to be formed through the photolithographic process.

Referring to FIG. 7E, the RDL process is performed on the back side. A seed layer (not shown) may be formed on the back side B of the molding member 300 and the second via hole 302. The seed layer may be formed through a deposition process or electro-less plating. Electroplating is performed by using the seed layer as seed so that the conductive material 304 may be formed on the molding member 300 and the second via hole 302. The CMP process is performed on the conductive material 304 on the back side B of the molding member 300 so that the thickness of the conductive material 304 becomes constant.

Referring to FIG. 7F, the external terminal 330b is formed through the pattering process of the conductive material 304. It is possible to simultaneously form the second through-electrode 310 and the external terminal 330b through the photolithographic process of the conductive material 304. In this case, the external terminal 330b may also be formed on the first through-electrode 110. Subsequently, the passivation layer 340 that exposes the external terminal 330b may be formed.

Referring to FIG. 7G, the RDL process of the top side T is performed. The conductive material 304 is deposited on the top side T of the molding member 300, the CMP is performed and then the internal terminal 330a is formed by using a patterning process. Subsequently, the passivation layer 340 that exposes the internal terminal 330a may be formed. Accordingly, the circuit board C including at least the interposer 100 may be manufactured.

In the following, a method of manufacturing the electronic module M by using the circuit board C having the interposer embedded therein is described in detail with reference to the drawings.

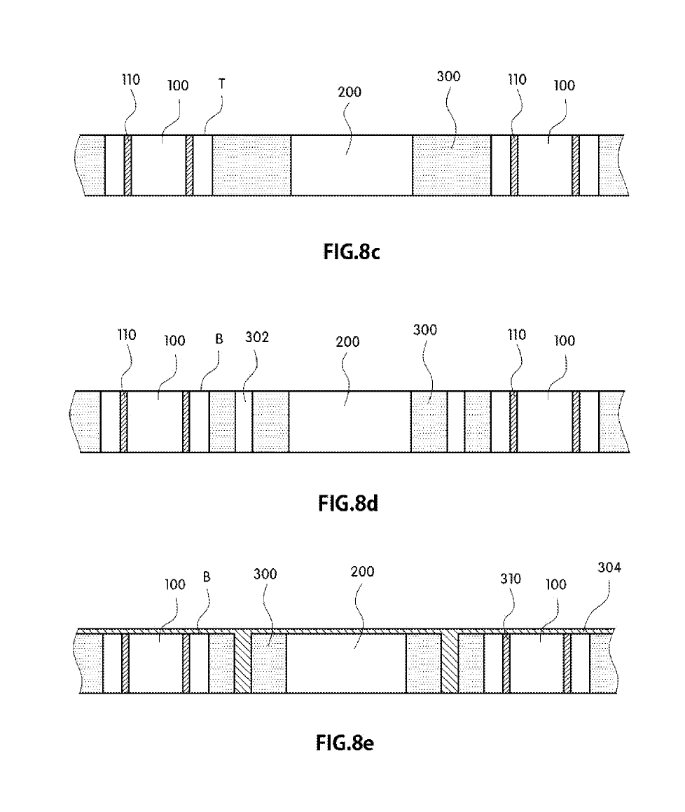

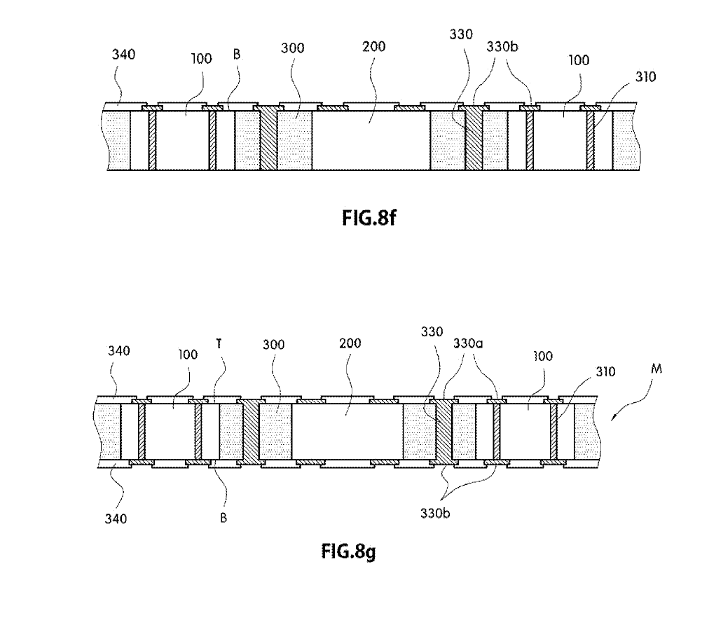

FIGS. 8A to 8F are cross-sectional views of a method of the electronic module of FIG. 4, i.e., a method of manufacturing the electronic module by using the circuit board having the interposer embedded therein.

Referring to FIG. 8A, the interposer 100 may be molded along with the first element 200. The interposer 100 and the first element 200 are arranged at a certain interval on the molding carrier 270. The back side B of the interposer 100 and the first element 200 may be fixed to the molding carrier 270 by using adhesive.

Referring to FIG. 8B, the molding carrier 270 is coated with the insulating material 290 so that the interposer 100 and the first element 200 may be sufficiently covered. The molding carrier 270 is removed with the adhesive.

Referring to FIG. 8C, the CMP process is performed until the interposer 100 and the first element 200 are exposed. A portion of the insulating material 290 is removed so that the top side T of the interposer 100 and the firs element 200 is exposed. At the same time, the molding member 300 having substantially the same level as the top side T of the interposer 100 and the first element 200 is formed. In another embodiment, the height of the first element 200 may be lower than that of the interposer 100 as shown in FIG. 3. In this case, through the CMP process, the interposer may be exposed but the first element 200 may not be exposed.

Referring to FIG. 8D, by patterning the back side B of the molding member 300, the second via hole 302 passing through the molding member 300 is formed. The second via hole 302 may be formed through a photolithographic process or laser process.

Referring to FIG. 8E, the RDL process is performed on the back side B. By performing electroplating on the back side B of the molding member 300 and the second via hole 302, the conductive material 304 including copper (Cu) may be formed.

Referring to FIG. 8F, the external terminal 330b is formed through the pattering process of the conductive material 304. It is possible to simultaneously form the second through-electrode 310 and the external terminal 330b through the photolithographic process of the conductive material 304. In this case, the external terminal 330b may also be formed on the first through-electrode 110. Subsequently, the passivation layer 340 that exposes the external terminal 330b may be formed.

Referring to FIG. 8G, the RDL process of the top side

T is performed. It is possible to form the internal terminal 330a on the top side T of the molding member 300 and form the passivation layer 340 that exposes the internal terminal 330a.

Referring back to FIG. 4, the second element 400 and/or the third element 500 are stacked on the top side T. The second and third elements 400 and 500 are electrically connected to the first and second through-electrodes 110 and 310 through the internal terminal 330a so that the electronic module M in which elements organically operate is manufactured.

### INDUSTRIAL APPLICABILITY

As discussed above, the circuit board of the present invention maximizes the advantage of an insulator and the advantage of a semiconductor because the molding member being the insulator is coupled to the interposer being the semiconductor, and more particularly, the present invention may be widely used for a fan-out WLP that simultaneously improves mechanical strength and degree of integration by partly applying the silicon interposer to a base requiring the fine-pitch through hole.

1. A circuit board having an interposer embedded therein, the circuit board comprising:
an interposer having a top side and a back side that are electrically connected by a first through-electrode; and
a molding member in which the interposer is embedded, wherein the molding member exposes the top side and back side of the interposer.

2. The circuit board of claim 1, further comprising a second through-electrode that electrically connects top and back sides of the molding member,
wherein a fine pitch of the first through-electrode is smaller than that of the second through-electrode.

3. An electronic module using a circuit board having an interposer embedded therein, the electronic module comprising:
an interposer having a top side and a back side that are electrically connected by a first through-electrode; and
a first element disposed on substantially a same plane as the interposer; and
a molding member in which the interposer and the first element are embedded, wherein a second through-electrode electrically connects top and back sides of the molding member.

4. The electronic module of claim 3, wherein both the top and back sides of the interposer are exposed.

5. The electronic module of claim 4, wherein the top side of the first element is not exposed and the back side of the first element is exposed.

6. The electronic module of claim 3, further comprising:
a second element connected to an external circuit by the first through-electrode; and
a third element connected to the external circuit by the second through-electrode.

7. The electronic module of claim 6, wherein the first element is a logic semiconductor chip,
the second element is a memory semiconductor chip, and
the third element is a passive element including a resistor or a condenser.

8. The electronic module of claim 6, further comprising an external terminal at the back side and an internal terminal at the top side to connect the second element or the third element to the external circuit.

9. The electronic module of claim 8, wherein the second element further comprises a redistribution pattern electrically connected to the external terminal.

10. A method of manufacturing a circuit board having an interposer embedded therein, the method comprising:
providing an interposer having a first through electrode;
disposing the interposer on a molding carrier;
coating the interposer with a molding material;
removing the molding carrier;
performing polishing to form a molding member having substantially a same level as a top side of the interposer, until the top side of the interposer is exposed; and
forming a second through-electrode passing through the molding member.

11. The method of claim 10, wherein the providing of the interposer having the first through-electrode comprises:
forming a first via hole having a certain depth on an interposer substrate by using a photolithography process;
performing copper electroplating on the first via hole to form the first through-electrode;
thinning a back side of the interposer substrate to expose the first through-electrode; and
dicing the interposer substrate to form a plurality of interposers.

12. The method of claim 11, wherein the forming of the second through-electrode passing through the molding member comprises:
forming a second via hole in the molding member by using a laser process; and
performing copper electroplating on the second via hole to form a second through-electrode.

13. The method of claim 12, wherein the forming of the second through-electrode comprises:
performing copper electroplating on back sides of the interposer and the molding member to form a conductive layer; and
patterning the conductive layer to simultaneously form an external terminal electrically connected to the first through-electrode and an external terminal electrically connected to the second through-electrode.

14. A method of manufacturing an electronic module using a circuit board having an interposer embedded therein, the method comprising:
providing an interposer having a first through electrode;
disposing the interposer and a first element on a molding carrier;
coating the interposer and the first element with a molding material;
removing the molding carrier;
performing polishing to form a molding member having substantially a same level as a top side of the interposer, until the top side of the interposer is exposed; and
forming a second through-electrode passing through the molding member.

15. The method of claim 14, further comprising stacking a second element electrically connected to the first through-electrode on the interposer.

16. The method of claim 15, further comprising stacking a third element electrically connected to the second through-electrode on the molding member.
